(19) United States
(12) Patent Application Publication
(10) Pub. No.: US 2006/0270109 A1
(43) Pub. Date: Nov. 30, 2006

(54) Manufacturing method for an electronic component assembly and corresponding electronic component assembly

(76) Inventors: Stephan Blaszczak, Freyburg (DE); Martin Reiss, Dresden (DE); Bernd Scheibe, Dresden (DE); Steffen Kroehnert, Dresden (DE); Knut Kahlisch, Dresden (DE); Ingolf Rau, Dresden (DE); Harry Hedler, Germering (DE); Soo Gil Park, Dresden (DE)

Correspondence Address: JENKINS, WILSON, TAYLOR & HUNT, P. A., 3100 TOWER BLVD, SUITE 1200, DURHAM, NC, 27707, US

(21) Appl. No.: 11/140,687

(22) Filed: May 31, 2005

(51) Int. Cl. H01L 21/00

(52) U.S. Cl. 438/108; 438/127; 438/106

(57) ABSTRACT

Manufacturing method for an electronic component assembly and corresponding electronic component assembly The present invention provides a manufacturing method for an electronic component assembly and to a corresponding electronic component assembly. The method comprises the steps of: providing a substrate having a first and a second side and having at least one through-hole, said second side having a first plurality of solder connection pads; attaching a semiconductor chip to said first side of said substrate; performing a mould process on said substrate and said attached semiconductor chip so as to obtain a mould package, said mould package including at least one first mould section covering said semiconductor chip on the first side and at least one second mould section extending through said throughhole and protruding over said solder connection pads on the second side; and providing a printed circuit board having a surface with a second plurality of solder connection pads corresponding to said first plurality of solder connection pads; and soldering said mould package to said printed circuit board by means of solder balls between said first and second plurality of solder connection pads such that said at least one second section forms a spacer structure supporting said mould package on said surface of said printed circuit board.

The present invention relates to a manufacturing method for an electronic component assembly and to a corresponding electronic component assembly.

Although in principle applicable to arbitrary integrated circuits, the following invention and the underlying problems will be explained with respect to integrated memory circuits in silicon technology.

U.S. 2002/0162679 A1 discloses surface mount packages having pre-applied underfill thereon and methods of fabricating and using such packages. Supplying customers with packages having pre-applied underfill enhances the thermal and mechanical reliability of surface mount packages and also, mitigates the customers' needs for additional cost, tooling, man-power, and process operations relating to the application and curing of the underfill material.

In general, all grid array packages are often used to connect an electronic component assembly to a printed circuit board. Here, the solder balls have a dual function, namely as an electrical connection and as a mechanical connection to the printed circuit board.

Due to the thermal mismatch between the package and the printed circuit board there are often cracks in the solder balls after thermal cycling conditions which cause an electrical failure of the electric component.

In order to overcome these problems, an attempt has been made to match the thermal expansion coefficients of package and circuit board, f.e. by choosing appropriate materials or developing new materials for stress minimisation.

Also, additional design measures have been taken such as pad design solder bump magnitude, chip thickness, mould cap thickness, substrate thickness, adhesive thickness, and adhesive area magnitude.

However, all of these known measures which have been taken so far are not sufficient to solve the above mentioned drawbacks.

Thus, it is an object of the present invention to provide an improve manufacturing method for an electronic component assembly and a corresponding component assembly, wherein the stress due to the thermal mismatch is further minimized.

According to the present invention, this object is achieved by the manufacturing method of claim 1 and the assembly according to claim 8.

The basic idea underlying the present invention is using additional moulded structures on the package ball side which can act as a spacer to the printed circuit board in order to take away a big part of the mechanical stress which is otherwise directly effecting the solder joints. Optionally, these spacer structures can be glued to the printed circuit board.

Especially, the spacer structures prevent the package on bending in the direction to the printed circuit board. Furthermore, the spacer structures provide an defined stand-off of the package on the printed circuit board. The symmetry of the package is improved regarding the part of the mould compound which is placed on the die side and on the ball side of the substrate in order to achieve the spacer structures, through-holes are provided on well-defined places of the substrate, and the mould is designed such that through these through-holes the spacer structures are formed during the mould process. Thus, the spacer structure is directly integrated in the package by appropriately designing the substrate and the mould to it.

In the dependent claims, advantageous embodiments and improvements of the manufacturing method of claim 1 and the assembly of claim 8, respectively, are listed.

According to a preferred embodiment, said spacer structure is adhered to said printed circuit board by means of an adhesive layer.

According to another preferred embodiment, said solder balls are formed on said first plurality of solder connection pads befor said step of performing a mould process, and said second mould section is formed such that it encloses said solder balls and covers said second side between said solder balls.

According to another preferred embodiment, said second mould section is formed such that said solder balls protrude over its surface.

According to another preferred embodiment, said second mould section is formed such that said solder balls are flush with its surface.

According to another preferred embodiment, said substrate has a peripheral region around said attached semiconductor chip, and said throughhole is located in said peripheral region.

Preferred embodiments of the invention are depicted in the drawings and explained in the following description.

In the Figures:

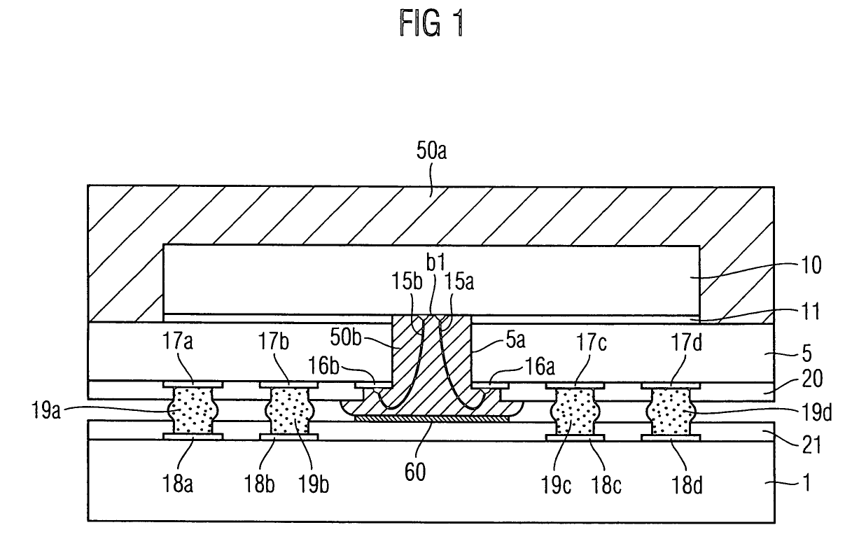

FIG. 1 shows a schematic cross-section of an electronic component assembly manufactured according to a first embodiment of the present invention;

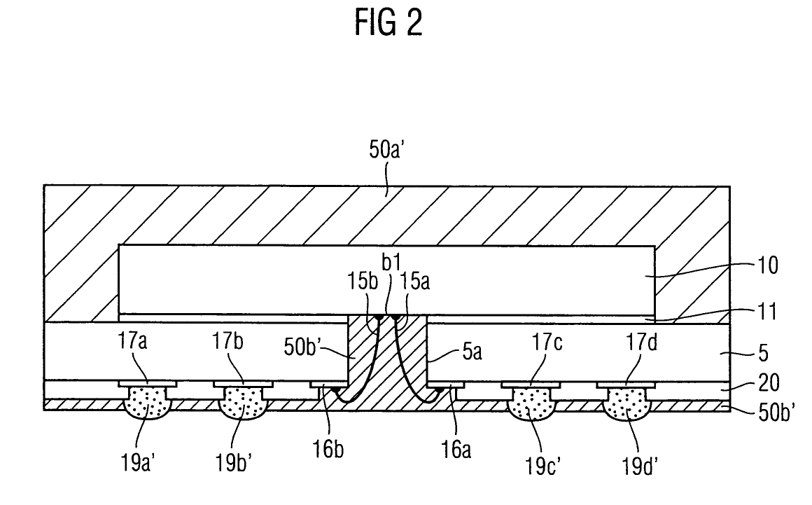

FIG. 2 shows a schematic cross-section of an electronic component assembly manufactured according to a second embodiment of the present invention;

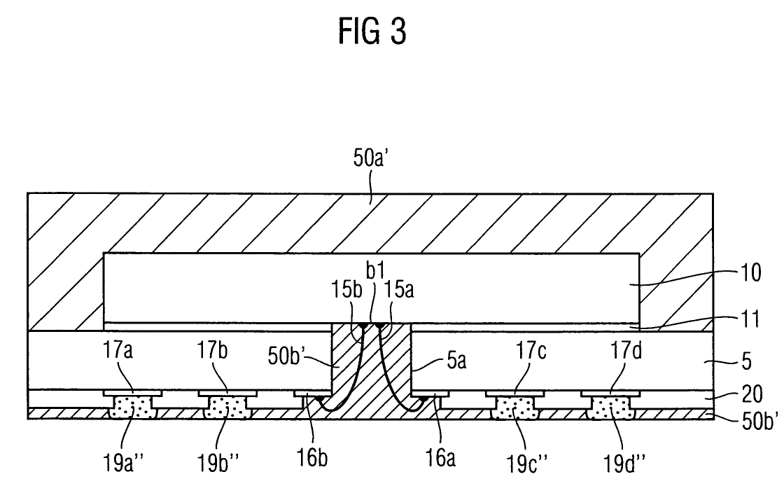

FIG. 3 shows a schematic cross-section of an electronic component assembly manufactured according to a third embodiment of the present invention;

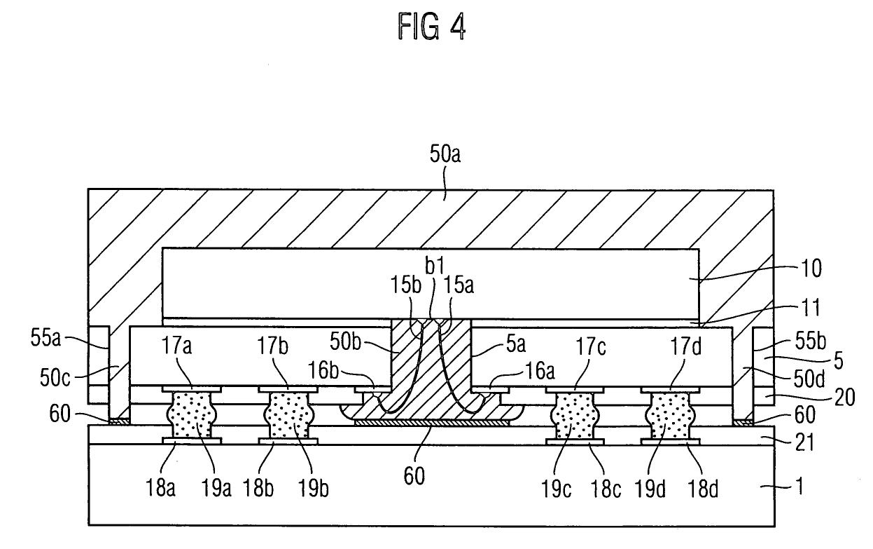

FIG. 4 shows a schematic cross-section of an electronic component assembly manufactured according to a fourth embodiment of the present invention;

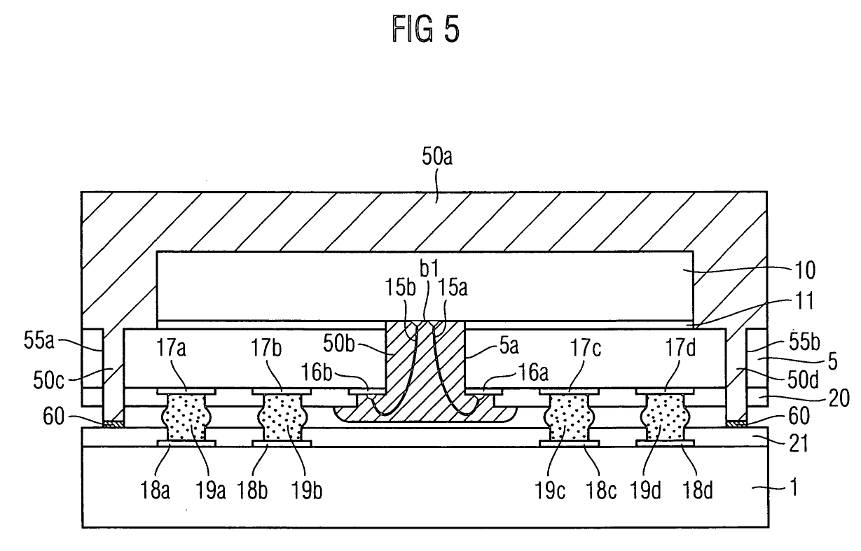

FIG. 5 shows a schematic cross-section of an electronic component assembly manufactured according to a fifth embodiment of the present invention; and

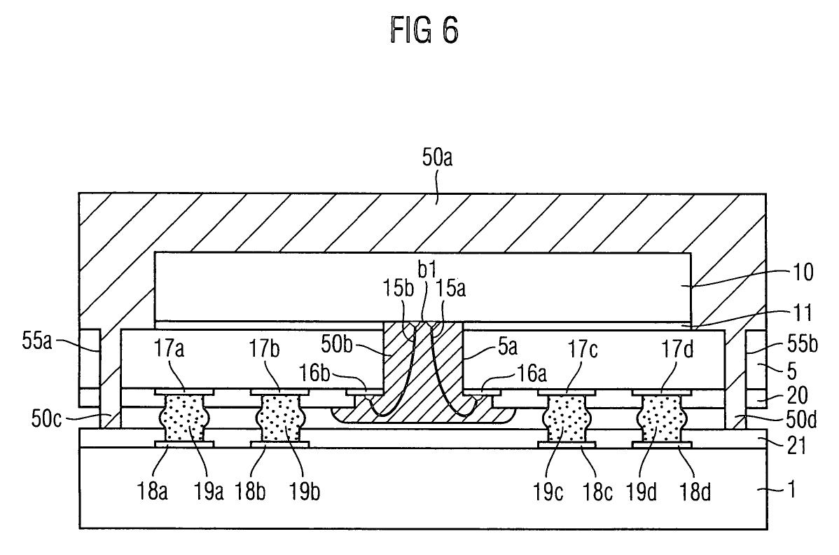

FIG. 6 shows a schematic cross-section of an electronic component assembly manufactured according to a sixth embodiment of the present invention.

In the Figures, identical reference signs denote equivalent or functionally equivalent components.

FIG. 1 shows a schematic cross-section of an electronic component assembly manufactured according to a first embodiment of the present invention.

In FIG. 1, reference sign 10 denotes a semiconductor memory chip which is attached to a substrate 5 by means of an adhesive layer 11. The substrate 5 is made of a plastic resin or any other suitable material. Provided in the substrate 5 is a through-hole 5a which is located around a bonding area b1 of the semiconductor chip 10. On the side of the substrate 5 which is turned away from the semiconductor chip 10 there are bonding lands 16a, 16b which are connected by bonding wires 15a, 15b to said bonding area b1 of said semiconductor chip 10.

Moreover, on this side of the substrate 5 there are also solder connection pads 17a-17d which are surrounded and partially overlapped by a solder stop layer 20.

Before the substrate 5 with the semiconductor chip 10 attached thereto is soldered to the printed circuit board 1, a mould process is performed in order to form a mould package comprising mould sections 50a, 50b. Mould section 50a has a cap structure and is formed over the semiconductor chip 10 and the surrounding substrate area. Mould section 50b is formed in the through-hole 5a and is raised with respect to the solder stop layer 20 so as to provide a spacer structure in this area. Mould section 50b also encapsulates the bond wires 15a, 15b. Thus, by performing such a mould package an integrated spacer structure formed by the mould section 50b has been established on the side of the substrate 5 which is turned away from this semiconductor chip 10.

In a next step, the printed circuit board having solder connection pads 18a-18d surrounded and partially overlapped by another solder stop layer 21 is provided. Then, an adhesive layer 60 is provided in the region of the solder stop layer 21 which is opposing the spacer structure formed by the mould section 50b and optionally also in the protruding part of the spacer structure. Then, the packaged substrate including the semiconductor chip 10 is soldered to the printed circuit board 1 by means of solder balls 19a to 19d and simultaneously the spacer structure formed by the mould section 50b is glued to the solder stop layer by means of the adhesive layer 60. The spacer structure formed by the mould section 50b serves as a stabilizing structure which reduces or prevents the bending of the substrate towards the printed circuit board 1 under thermal cycling condictions. Thus, a staple ball grid array package is established in which the stress due to thermal mismatch of the substrate 5 and the circuit board 1 has been minimized and where the longterm stability of the solder balls 19a to 19d has been improved.

FIG. 2 shows a schematic cross-section of an electronic component assembly manufactured according to a second embodiment of the present invention.

In the second embodiment shown in FIG. 2, there are also two mould sections 50a′, 50b′, however, in contrast to the first embodiment the second mould section 50b′ is provided such that it encloses the solder balls 19a′ to 19d′ provided on the solder connection pads 17a to 17d on the side of the substrate 5 turned away from the semiconductor chip 10 in advance. This has the advantage that the second mould section 50b′ may not only serve as a spacer structure, but also for stabilization of the solder balls by embedding said solder balls in the mould. Particularly, the critical region of the intermetallic face at the enter face between the connection pads 17a to 17d and the solder balls 19a′ to 19d′ are stabilized.

As may be obtained from FIG. 2, the solder balls 19a′ to 19d′ slightly protrude above the mould section 50b′. When attaching this moulded chip package to connection pads 18a to 18d of the printed circuit board 1 (see FIG. 1), some care needs to be taken that not to much solder creeps into the space between the mould section 50b′ and the solder stop layer 21. However, this may be achieved by a routine design measure.

FIG. 3 shows a schematic cross-section of an electronic component assembly manufactured according to a third embodiment of the present invention.

The embodiment shown in FIG. 3 is nearly identical to the above described second embodiment according to FIG. 2 with the exception that the solder balls 19a″ to 19d″ do not protrude over the second mould section 50b′. This may be achieved by an appropriate design of the mould tool where the solder balls are slightly flattened during the moulding which leads to larger contact areas.

As in the second embodiment, the spacer structure formed by the second mould section 50b′ serves as the stabilizer for preventing bending of the substrate 5 towards the printed circuit board 1 during thermal cycling and also for stabilizing the pre-formed solder balls 19a″ to 19d″.

FIG. 4 shows a schematic cross-section of an electronic component assembly manufactured according to a fourth embodiment of the present invention.

The fourth embodiment shown in FIG. 4 is identical to the first embodiment of FIG. 1 with the exception that the substrate 5 comprises further through-holes 55a, 55b in the periphery of the substrate 5 with regard to the chip 10, in which through-holes 55a, 55b third and fourth mould sections 50c, 50d are formed which also serve as spacer and which also are glued to the solder stop layer 21 on the printed circuit board 1 by means of the adhesive layer 60. By providing these additional spacer structures formed by the mould sections 50c, 50d further enhance stability against bending during thermal cycling may be achieved.

FIG. 5 shows a schematic cross-section of an electronic component assembly manufactured according to a fifth embodiment of the present invention.

In the fifth embodiment shown in FIG. 5, the glue layer 60 is omitted in the region of the mould section 50b in the center through-hole of the substrate such that in this region the mould section 50b′ only serves for encapsulating the bond wires 50a, 50b. In other words, in this embodiment the spacer function is fully obtained by the mould sections 50c, 50d. It should be mentioned that the depicted cross-section only shows to spacer structures in form of mould sections 50c, 50d, however considering the full plane of this structure there would be more spacers in order to achieve an optimum stabilizing and balancing effect.

FIG. 6 shows a schematic cross-section of an electronic component assembly manufactured according to a sixth embodiment of the present invention.

In the sixth embodiment shown in FIG. 6, the adhesive layer 60 has also been omitted between the solder stop layer 21 and the spacer structures formed by mould sections 50c, 50d. Here, the connection between the moulded package and the printed circuit board is only formed by the solder balls 19a to 19d. However, of course the spacer structures formed by the mould sections 50c, 50d fulfill the same stabilizing effects as in all other embodiments.

Although the present invention has been described with respect to two preferred embodiments, it is not limited thereto, but can be modified in various manners which are obvious for the person skilled in the art.

Particularly, the selection of the materials and the geometries is only an example and can be varied variously.

### LIST OF REFERENCE SIGNS

| | |
|---|---|
| 1 | Printed circuit board |
| 18a-18d | connection pads |
| 20, 21 | solder layers |
| 19a-19d | solder balls |
| 19a′-19d′ | solder balls |
| 19a″-19d″ | solder balls |
| 17a-17d | connection pads |
| 16a, 16b | bond lands |
| b1 | bond area |
| 15a, 15b | bond wires |
| 10 | semiconductor chip |
| 11 | adhesive layer |
| 60 | adhesive layer |
| 50a, 50b | mould sections |
| 50c, 50d | mould sections |
| 50a′, 50b′ | mould sections |

1. A manufacturing method for an electronic component assembly, comprising the steps of:
(a) providing a substrate having a first and a second side and having at least one throughhole, said second side having a first plurality of solder connection pads;
(b) attaching a semiconductor chip to said first side of said substrate;
(c) performing a mould process on said substrate and said attached semiconductor chip so as to obtain a mould package, said mould package including at least one first mould section covering said semiconductor chip on the first side and at least one second mould section extending through said throughhole and protruding over said solder connection pads on the second side;
(d) providing a printed circuit board having a surface with a second plurality of solder connection pads corresponding to said first plurality of solder connection pads; and
(e) soldering said mould package to said printed circuit board by means of solder balls between said first and second plurality of solder connection pads such that said at least one second section forms a spacer structure supporting said mould package on said surface of said printed circuit board.

2. The method according to claim 1, wherein said throughhole is located under a bonding area of said attached semiconductor chip, wherein said second side has a plurality of bonding pads which are connected by bonding wires to said bonding area, and wherein said second mould section is formed such that it encapsulates said bonding area, bond wires and bonding pads.

3. The method according to claim 1, wherein said spacer structure is adhered to said printed circuit board by means of an adhesive layer.

4. The method according to claim 1, wherein said solder balls are formed on said first plurality of solder connection pads before said step of performing a mould process, and wherein said second mould section is formed such that it encloses said solder balls and covers said second side between said solder balls.

5. The method according to claim 4, wherein said second mould section is formed such that said solder balls protrude over its surface.

6. The method according to claim 4, wherein said second mould section is formed such that said solder balls are flush with its surface.

7. The method according to claim 1, wherein said substrate has a peripheral region around said attached semiconductor chip, and wherein said throughhole is located in said peripheral region.

8. An electronic component assembly, comprising
(a) a substrate having a first and a second side and having at least one throughhole, said second side having a first plurality of solder connection pads;
(b) a semiconductor chip attached to said first side of said substrate;
(c) a mould package on said substrate and said attached semiconductor chip, said including at least one first mould section covering said semiconductor chip on the first side and at least one second mould section extending through said throughhole and protruding over said solder connection pads on the second side; and
(d) a printed circuit board having a surface with a second plurality of solder connection pads corresponding to said first plurality of solder connection pads; and
(e) said mould package to said printed circuit board being connected by means of solder balls between said first and second plurality of solder connection pads such that said at least one second section forms a spacer structure supporting said mould package on said surface of said printed circuit board.

9. The assembly according to claim 8, wherein said throughhole is located under bonding area of said attached semiconductor chip, wherein said second side has a plurality of bonding pads which are connected by bonding wires to said bonding area, and wherein said second mould section is formed such that it encapsulates said bonding area, bond wires and bonding pads.

10. The assembly according to claim 8, wherein said spacer structure is adhered to said printed circuit board by means of an adhesive layer.

11. The assembly according to claim 8, wherein said second mould section is formed such that it encloses said solder balls and covers said second side between said solder balls.

12. The assembly according to claim 8, wherein said substrate has a peripheral region around said attached semiconductor chip, and wherein said throughhole is located in said peripheral region.
